(19) United States
(12) Patent Application Publication
(10) Pub. No.: US 2011/0241169 A1
(43) Pub. Date: Oct. 6, 2011

(54) METHOD OF MANUFACTURING SEMICONDUCTOR DEVICE AND SEMICONDUCTOR DEVICE

(75) Inventor: TOMOHIKO HIGASHINO, KANAGAWA (JP)

(73) Assignee: RENESAS ELECTRONICS CORPORATION, KANAGAWA (JP)

(21) Appl. No.: 13/070,503

(22) Filed: Mar. 24, 2011

(30) Foreign Application Priority Data
Mar. 30, 2010 (JP) 2010-077002

(51) Int. Cl. H01L 29/92; H01L 21/02

(52) U.S. Cl. 257/532; 438/381; 257/E21.008; 257/E29.342

(57) ABSTRACT

A capacitor having a cylindrical shape is increased in capacitance, and a high-resistance region is prevented from being formed in a lower electrode. A semiconductor device includes a capacitor formed to have a cylindrical shape. The semiconductor device includes an insulating film formed over a substrate, a lower electrode formed to have a cylindrical shape, and including a first metal film which is not formed at a bottom portion in a depressed portion provided in the insulating film, but is selectively formed at a sidewall therein and a second metal film which is formed over the bottom portion in the depressed portion and over the first metal film at the sidewall therein, a capacitive film formed over the lower electrode, and an upper electrode formed over the capacitive film.

### CROSS-REFERENCE TO RELATED APPLICATION

The disclosure of Japanese Patent Application No. 2010-77002 filed on Mar. 30, 2010 including the specification, drawings and abstract is incorporated herein by reference in its entirety.

### BACKGROUND

1. Field of the Invention

The present invention relates to a method of manufacturing a semiconductor device and the semiconductor device, and particularly to a method of manufacturing a semiconductor device including a capacitor having a cylindrical shape and the semiconductor device.

2. Description of Related Art

With the miniaturization of an embedded DRAM-logic circuit product and a single DRAM memory, it has been extremely difficult to ensure the capacity of a DRAM therein. To ensure the capacity, it is examined to, e.g., increase the surface area of a lower electrode. To increase the surface area of the lower electrode of the capacitor portion of the DRAM without trading off a cell size, a cylindrical shape (cylinder shape) has been adopted as the shape of the capacitor portion of the DRAM.

Japanese Unexamined Patent Publication No. 2008-192650 discloses a semiconductor device having a silicon film formed to cover the bottom surface and side surface of a deep-hole cylinder for a capacitor which is provided to extend through an interlayer insulating film, and a capacitor having a lower metal electrode, a capacitive insulating film, and an upper electrode. The silicon film has a silicide layer resulting from a reaction with a metal forming the lower metal electrode in the vicinity of the interface with the lower metal electrode. This allows electric resistance between the capacitor and a capacitive contact plug to be reduced to a small value, and allows a high yield to be obtained.

Japanese Unexamined Patent Publication No. 2005-217189 discloses a configuration in which a hydrogen barrier film formed of TiAlN is disposed at each of the bottom portion and sidewall of a hole, and a lower electrode is formed thereover.

### SUMMARY

To increase the capacitance of a capacitor having a cylindrical shape, it can be considered to enlarge the capacitor portion of a DRAM in a height direction perpendicular to a substrate surface. When the DRAM capacitor portion is enlarged in the height direction, the depth of a cylinder is increased to increase the aspect ratio of the cylinder. However, if the aspect ratio of the cylinder is increased, when a depressed portion is formed in an insulating film and a lower electrode is formed in the depressed portion, it becomes difficult to uniformly form a metal film forming the lower electrode. In particular, at the sidewall of the depressed portion, thickness variations in the metal film are likely to occur. When the thickness of the metal film forming the lower electrode becomes non-uniform and, in particular, a portion where the metal film is too thin to be formed at the sidewall of the depressed portion is formed, a high-resistance region is formed locally.

FIGS. 11(a) and 11(b) are circuit diagrams each showing a configuration of a capacitor of a DRAM.

FIG. 11(a) shows an ideal circuit configuration of a capacitor 30 of the DRAM. Here, a lower electrode 31 is coupled to the transistor, an upper electrode 38 is coupled to a potential Vp, and an effective capacitance value (capacitance value when resistance is zero) of the capacitor 30 is Cs. However, if a local high-resistance region is formed in the lower electrode 31 of the capacitor 30, when “H” is written in a DRAM cell, a capacitor C1 closer to a substrate surface (plug) and a capacitor C2 more distant therefrom are formed with the local high-resistance region interposed therebetween, as shown in FIG. 11(b). At this time, the effective capacitance value of the capacitor 30 is C1+α×C2 (0<α<1), where α represents a capacitive component which cannot be read into the transistor due to the high-resistance region during reading or a capacitive component which cannot be written within a write time during writing. As the resistance increases, α decreases. Thus, when thickness variations occur in the metal film to form the local high-resistance region and increase the resistance of the lower electrode, the effective capacitance value of the capacitance 30 undesirably decreases.

On the other hand, if the thickness of the metal film formed in the depressed portion is increased to prevent such a high-resistance region from being formed, the thickness of the metal film formed at the bottom portion of the depressed portion increases to eliminate the effect obtained by enlarging the DRAM capacitor portion in the height direction. Such a problem has not been solved heretofore.

The present invention provides a method of manufacturing a semiconductor device, including the steps of: forming an insulating film over a substrate; forming a depressed portion in the insulating film; and forming, in the depressed portion, a capacitor having a cylindrical shape, and including a lower electrode, a capacitive film formed over the lower electrode, and an upper electrode formed over the capacitive film, wherein the step of forming the capacitor includes the steps of: forming a first metal film over an entire upper surface of the substrate to form the first metal film in the depressed portion; performing anisotropic dry etching to selectively remove the first metal film at a bottom portion of the depressed portion, and leave the first metal film only at a sidewall of the depressed portion; and forming a second metal film over the entire upper surface of the substrate to form the second metal film over the bottom portion in the depressed portion and over the first metal film at the sidewall therein, and thereby form the lower electrode including the first metal film and the second metal film.

The present invention provides a semiconductor device including a capacitor formed to have a cylindrical shape, including: a substrate; an insulating film formed over the substrate; a lower electrode including a first metal film which is not formed at a bottom portion in a depressed portion provided in the insulating film, but is formed at a sidewall therein, and a second metal film which is formed over the bottom portion in the depressed portion and over the first metal film at the sidewall therein; a capacitive film formed over the lower electrode; and an upper electrode formed over the capacitive film.

In the arrangement, after the first metal film is selectively formed only at the sidewall in the depressed portion, the second metal film is further formed. This allows the film thickness of the lower electrode to be sufficiently ensured even at the sidewall in the depressed portion where, in particular, the film thickness tends to be smaller. Therefore, even when the aspect ratio of the depressed portion is high, it is possible to prevent a high-resistance region from being formed in the lower electrode. In addition, since the first metal film is selectively left only at the sidewall of the depressed portion, the bottom portion of the lower electrode can be formed to have a reduced film thickness. By thus reducing the film thickness of the lower electrode at the bottom portion of the depressed portion, it is possible to prevent a reduction in the area of the lower electrode, and increase the capacitance of the capacitor. As a result, it is possible to increase the capacitance of the capacitor having a cylindrical shape, and prevent a high-resistance region from being formed in the lower electrode.

Note that any arbitrary combination of the aforementioned components and expressions of the present invention changed among a method, a device, and so forth are also effective as embodiments of the present invention.

According to the present invention, it is possible to increase the capacitance of the capacitor having the cylindrical shape, and prevent a high-resistance region from being formed in the lower electrode.

### BRIEF DESCRIPTION OF THE DRAWINGS

FIG. 1 is a cross-sectional view showing an example of a configuration of a semiconductor device in an embodiment of the present invention;

FIG. 2 is a process cross-sectional view showing a procedure for manufacturing the semiconductor device in the embodiment;

FIG. 3 is a process cross-sectional view showing the procedure for manufacturing the semiconductor device in the embodiment;

FIG. 4 is a process cross-sectional view showing the procedure for manufacturing the semiconductor device in the embodiment;

FIG. 5 is a process cross-sectional view showing the procedure for manufacturing the semiconductor device in the embodiment;

FIG. 6 is a process cross-sectional view showing the procedure for manufacturing the semiconductor device in the embodiment;

FIG. 7 is a process cross-sectional view showing the procedure for manufacturing the semiconductor device in the embodiment;

FIG. 8 is a process cross-sectional view showing the procedure for manufacturing the semiconductor device in the embodiment;

FIG. 9 is a process cross-sectional view showing the procedure for manufacturing the semiconductor device in the embodiment;

FIG. 10 is a cross-sectional view showing another example of the configuration of the semiconductor device in the embodiment; and

FIGS. 11(a) and 11(b) are circuit diagrams each showing a configuration of a capacitor of a DRAM.

### DESCRIPTION OF THE PREFERRED EMBODIMENTS

Embodiments of the present invention will be described hereinbelow with reference to the drawings. Note that, throughout all the drawings, the same components are designated by the same reference numerals, and a description thereof is omitted as necessary.

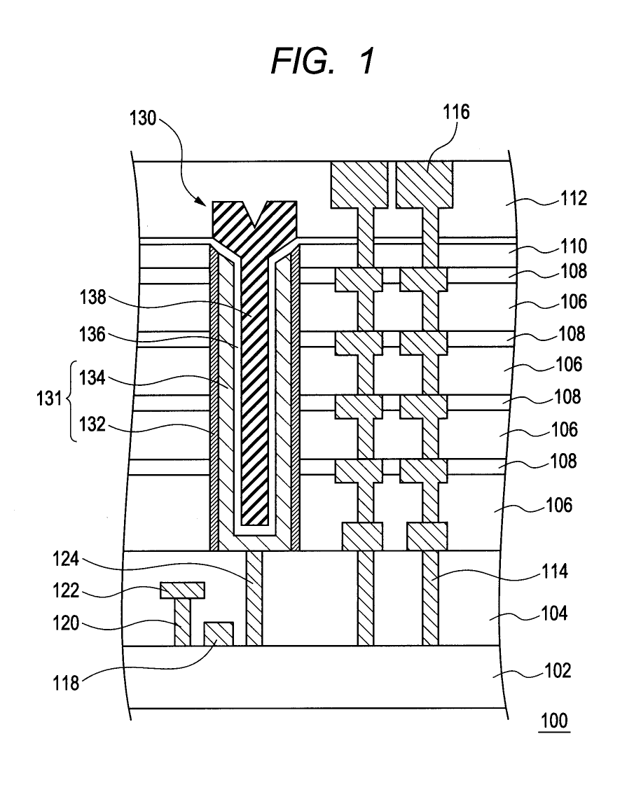

FIG. 1 is a cross-sectional view showing a configuration of a semiconductor device in an embodiment of the present invention.

A semiconductor device 100 includes a substrate 102, an interlayer insulating film 104 formed over the substrate 102, a plurality of interlayer insulating films 106 and 108 which are alternately arranged thereover, an interlayer insulating film 110 further formed thereover, and an interlayer insulating film 112 further formed thereover.

The substrate 102 of the semiconductor device can be, e.g., a silicon substrate or the like. In the substrate 102, a transistor including a gate 118 is formed. In the interlayer insulating film 104, there are formed a contact 120, wiring 122 formed thereover, a contact 124, contacts 114, and the like. Each of the contacts 120, 124, and 114 is coupled to an impurity diffusion region in the substrate 102. Each of the contacts 120 and 124 can be coupled to the source or drain of the transistor including the gate 118. The interlayer insulating film 104 can be formed of, e.g., a silicon dioxide film (SiO₂) or the like. Here, the interlayer insulating film 104 is shown as a single layer film, but can be formed as a laminated film of a plurality of insulating films.

In each of a laminated structure of the interlayer insulating films 106 and 108, the interlayer insulating film, 110, and the insulating film 112, a wiring structure 116 is formed. The wiring structure 116 includes wiring and vias, and can be formed into, e.g., a dual-damascene wiring structure or a single-damascene wiring structure. Here, the wiring portion of the wiring structure 116 is mainly formed in the interlayer insulating films 108, while the via portion thereof is formed in the interlayer insulating films 106. Each of the interlayer insulating films 106 and 108 can be formed of a low-dielectric-constant film (Low-k film). In particular, the interlayer insulating film 108 in which the wiring is formed can be formed of a low-dielectric-constant film. Each of the interlayer insulating films 110 and 112 can be formed of, e.g., a silicon dioxide film (SiO₂) film or the like. Note that each of the interlayer insulating films can be formed into a laminated structure of a plurality of films including, e.g., an etching stopper film, a protective insulating film, and the like, though not shown.

In each of the laminated structure of the interlayer insulating films 106 and 108, and the interlayer insulating film 110, a capacitor 130 coupled to the contact 124 is formed. The capacitor 130 can be a MIM (Metal-Insulator-Metal) capacitor having a cylindrical shaper (cylinder shape). The capacitor 130 can be used as the capacitor of the DRAM.

In the following description, the laminated structure of the interlayer insulating films 106 and 108, and the interlayer insulating film 110, in each of which the capacitor 130 is formed, will be hereinafter referred to simply as insulating films. The capacitor 130 includes a lower electrode 131 formed to have a cylindrical shape in a depressed portion provided in the insulating films, a capacitive film 136 formed over the lower electrode 131, and an upper electrode 138 formed over the capacitive film 136. In the present embodiment, the lower electrode 131 includes a first metal film 132 which is not formed at a bottom portion in the depressed portion, but is selectively formed at a sidewall therein, and a second metal film 134 which is formed at the bottom portion in the depressed portion and over the first metal film 132 at the sidewall therein.

The first metal film 132 and the second metal film 134 may be formed of the same material or different materials. Each of the first metal film 132 and the second metal film 134 can be formed of a metal material such as, e.g., TiN, TaN, W, or WN. The capacitive film 136 can be formed of an oxide of one or more metal elements selected from the group consisting of, e.g., Zr, Hf, La, and Y. The upper electrode 138 can be formed of a metal material such as, e.g., TiN, TaN, or WN. The upper electrode 138 can also have a configuration in which, e.g., W or the like is formed over the metal material mentioned above. The upper electrode 138 fills up the depressed portion formed in the insulating films.

Next, referring to FIGS. 1 to 9, a procedure for manufacturing the capacitor 130 in the present embodiment will be described. FIGS. 1 to 9 are process cross-sectional views each showing the procedure for manufacturing the semiconductor device 100 in the present embodiment.

First, in accordance with a typical method, the transistor including the gate 118 is formed in the substrate 102, and an insulating film forming a part of the interlayer insulating film 104 is formed over the gate 118 over the substrate 102. In the insulating film, a contact hole is formed, and filled with a conductive material so that the contact 120 is formed. Then, the wiring 122 is formed over the insulating film, and another insulating film forming a part of the interlayer insulating film 104 is formed thereover. In this manner, the interlayer insulating film 104 is formed. Thereafter, contact holes are formed in the interlayer insulating film 104, and filled with a conductive material so that the contacts 114 and 124 are formed.

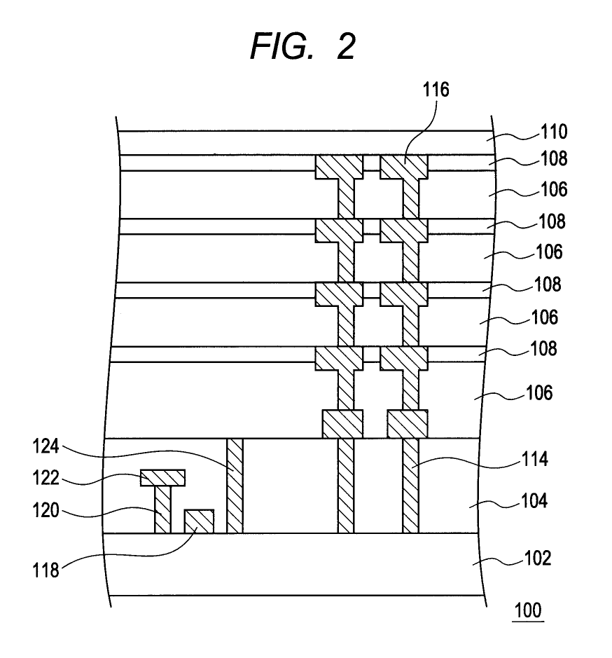

Subsequently, by a typical damascene method or the like, the laminated film of the interlayer insulating films 106 and 108, and a multilayer wiring structure comprised of the laminated film and the wiring structure 116 formed therein is formed. Thereafter, over the uppermost interlayer insulating film 108, the interlayer insulating film 110 is formed, resulting in the state shown in FIG. 2.

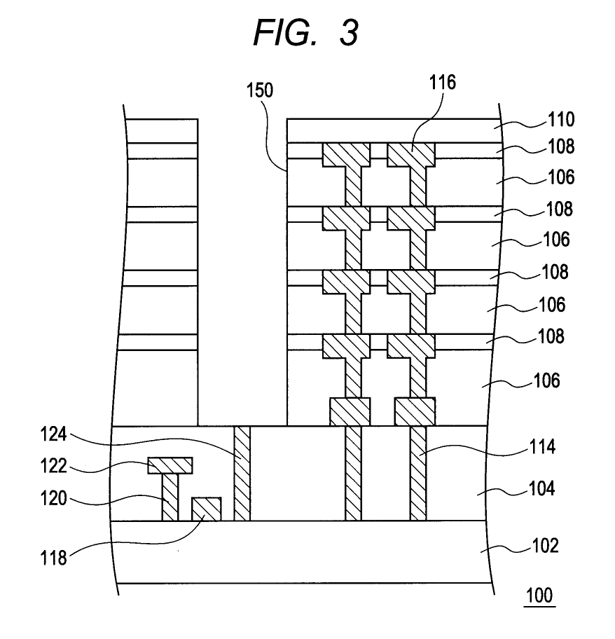

Next, using a typical lithographic technique, the laminated structure of the interlayer insulating films 106 and 108, and the interlayer insulating film 110 (hereinafter generally referred to simply as the insulating films) are subjected to dry etching, thereby forming a depressed portion 150 (FIG. 3). Here, at the bottom surface of the depressed portion 150, the contact 124 is exposed.

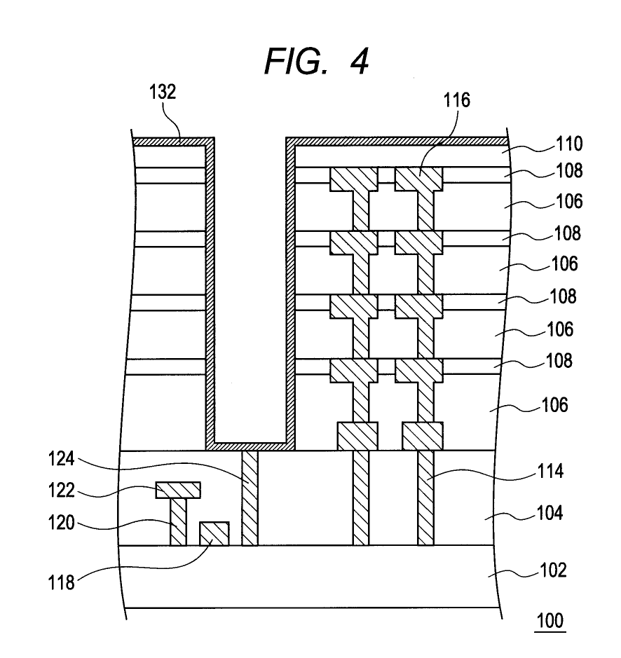

Thereafter, over the entire upper surface of the substrate 102 (in the depressed portion 150 and the interlayer insulating film 110), the first metal film 132 is formed (FIG. 4). The first metal film 132 can be formed by, e.g., chemical vapor deposition (CVD). In this manner, even when the aspect ratio of the depressed portion 150 is high, the first metal film 132 having a relatively uniform thickness can be deposited.

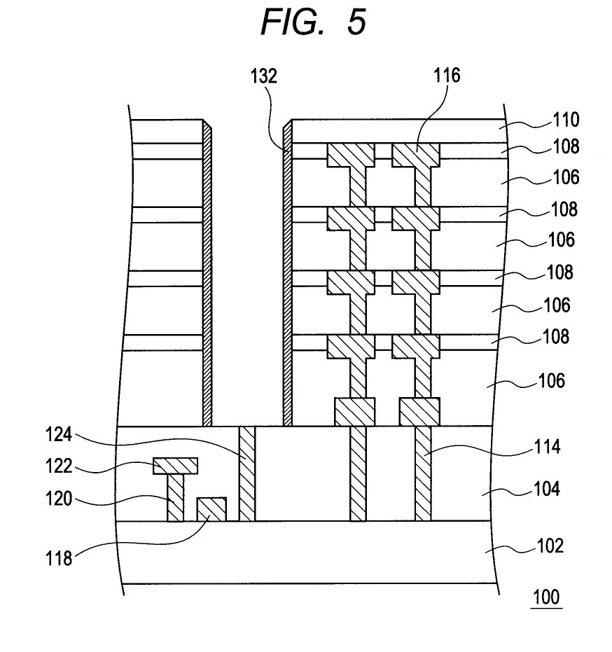

Subsequently, by anisotropic dry etching, the first metal film 132 over the surface of the interlayer insulating film 110 exposed at the bottom portion of the depressed portion 150 and outside the depressed portion 150 is selectively removed such that the first metal film 132 is selectively left only at the sidewall of the depressed portion 150 (FIG. 5). At this time, at the bottom surface of the depressed portion 150, the contact 124 is exposed. The thickness of the first metal film 132 at the sidewall of the depressed portion 150 can be adjusted to be, e.g., about not less than 5 nm and not more than 10 nm.

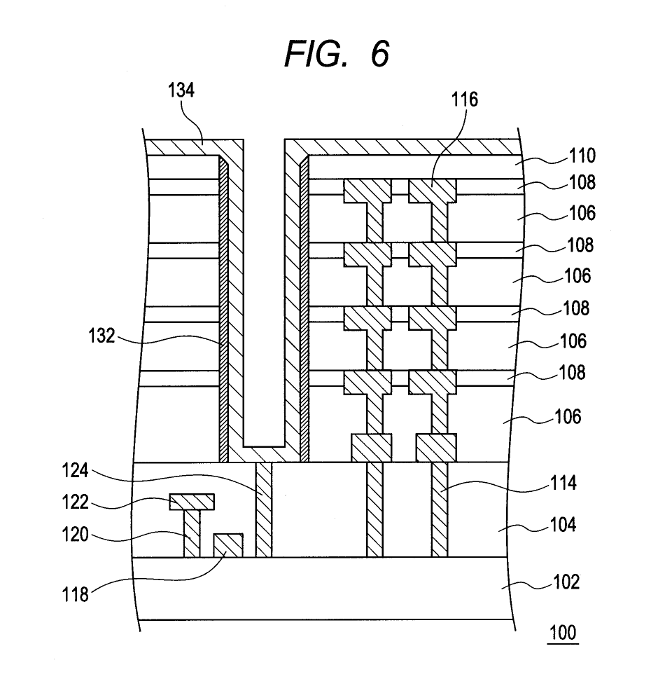

Next, by a wet process using, e.g., an organic chemical solution, the surface of the contact 124 is treated, and then the second metal film 134 is formed over the entire upper surface of the substrate 102 (in the depressed portion 150 and over the interlayer insulating film 110) (FIG. 6). The second metal film 134 can also be formed by, e.g., CVD. In the present embodiment, the second metal film 134 is coupled to the contact 124 exposed at the bottom portion of the depressed portion 150. Also, at the sidewall in the depressed portion 150, the second metal film 134 is formed over the first metal film 132. This allows the thickness of the metal film 131 forming the lower electrode to be adjusted to be, e.g., about not less than 10 nm and not more than 15 nm at the bottom portion of the depressed portion 150, and, e.g., about not less than 15 nm and not more than 20 nm at the sidewall of the depressed portion 150 (though the film thickness is smaller at the bottom portion than at the sidewall). When the film deposition is performed by, e.g., CVD, the film thickness normally tends to be smaller at the sidewall of the depressed portion than at the bottom portion thereof. However, in the present embodiment, the metal film 131 is formed at the sidewall of the depressed portion by the two film deposition steps, and therefore the film thickness at the sidewall can be increased. By way of example, no matter when the first metal film 132 is formed or when the second metal film 134 is formed, substantially the same film thickness can be set for a film deposition apparatus.

By the foregoing process, in the present embodiment, the lower electrode 131 can be formed to have a film thickness which is smaller at the bottom portion of the depressed portion 150 than at the sidewall thereof.

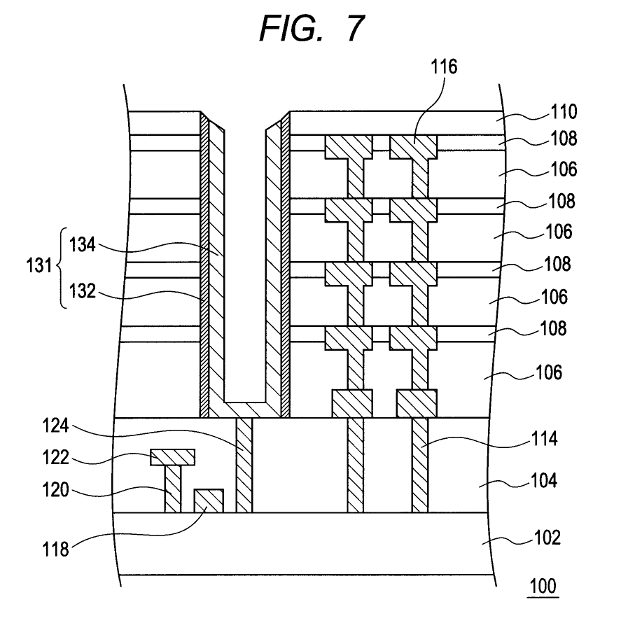

Subsequently, over the second metal film 134, sacrificial film (not shown) is formed so as to fill up the depressed portion 150. Then, the sacrificial film and the second metal film 134 are etched to remove the second metal film 134 exposed outside the depressed portion 150. Thereafter, the sacrificial film remaining in the depressed portion 150 is removed by etching. In this manner, the lower electrode 131 including the first metal film 132 and the second metal film 134 is formed (FIG. 7). At this time, the depressed portion 150 is not filled up with the lower electrode 131, and the depressed portion is still formed.

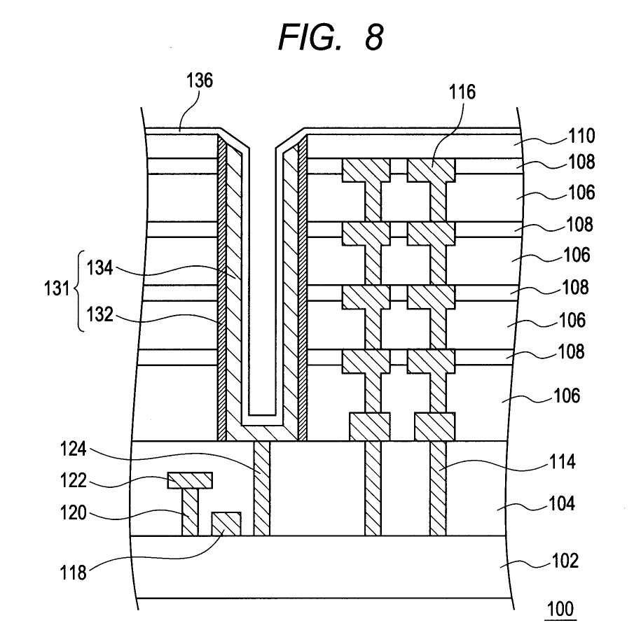

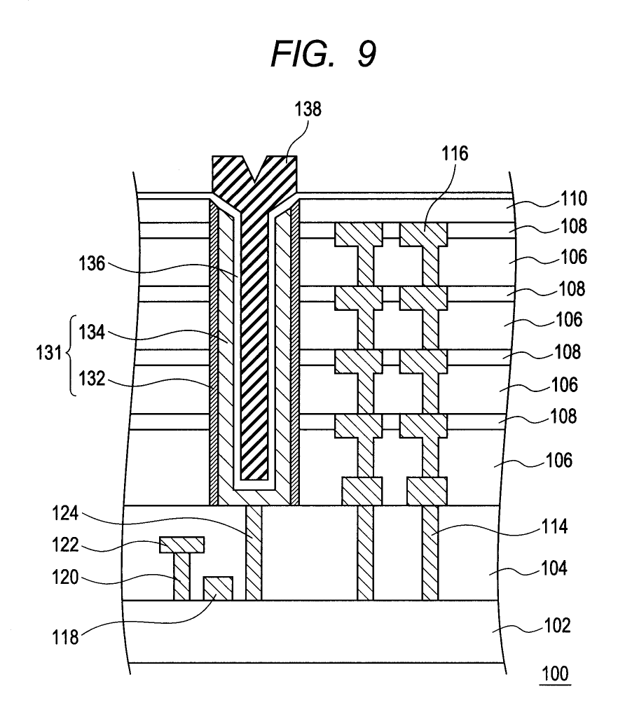

Thereafter, over the interlayer insulating film 110 and the lower electrode 131, the capacitive film 136 is formed (FIG. 8). Subsequently, over the capacitive film 136, the upper electrode 138 is formed (FIG. 9). The capacitive film 136 and the upper electrode 138 can be formed by a typical method for forming a capacitive film and an upper electrode for a capacitor having a cylindrical shape.

Thereafter, over the capacitive film 136 over the interlayer insulating film 110, the interlayer insulating film 112 is formed, and then the wiring structure 116 is formed in the interlayer insulating film 112. In this manner, the semiconductor device 100 having the configuration shown in FIG. 1 can be obtained.

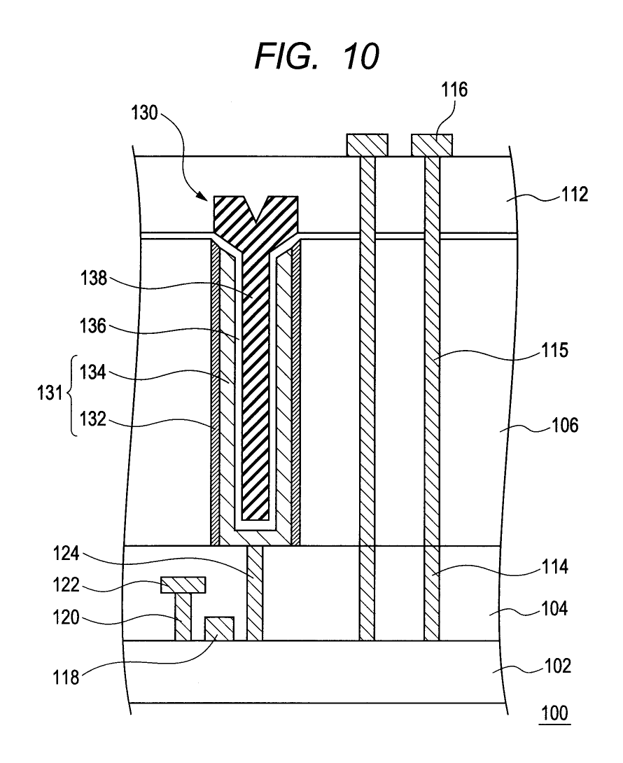

FIG. 10 is a cross-sectional view showing another example of the configuration of the semiconductor device 100 in the present embodiment.

In the example shown in FIGS. 1 to 9, the wiring structure 116 is formed in the insulating films in which the capacitor 130 is formed. By contrast, in the example shown in FIG. 10, only vias 115 (contacts) are formed in the interlayer insulating film 106 in which the capacitor 130 is formed. Here, the interlayer insulating film 106 is shown as a single layer film, but can be a laminated film of a plurality of insulating films. Otherwise, the interlayer insulating film 106 can also be formed of an insulating film other than a low-dielectric-constant film such as, e.g., a silicon dioxide film. Besides, the interlayer insulating film 106 can also have various other configurations.

Next, the effect of the semiconductor device 100 and a manufacturing procedure therefor in the present embodiment will be described.

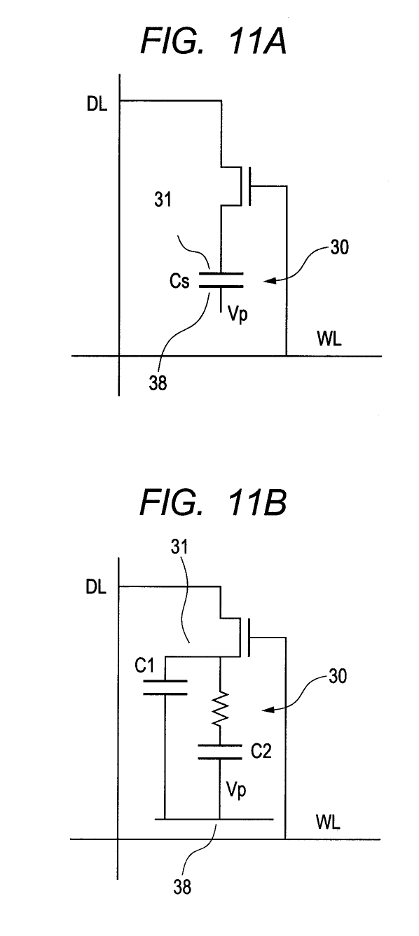

In the present embodiment, by the foregoing procedure for manufacturing the lower electrode 131, the first metal film 132 is selectively formed only at the sidewall in the depressed portion 150, and then the second metal film 134 is further formed. As a result, even at the sidewall in the depressed portion 150 where the film thickness tends to be smaller, a sufficient film thickness can be ensured to the lower electrode 131. Therefore, even when the aspect ratio of the depressed portion 150 is high, it is possible to prevent a high-resistance region from being formed in the lower electrode 131. This allows the capacitor 130 of the DRAM to have the same ideal circuit configuration as that of the capacitor 30 of the DRAM shown in FIG. 11(a).

By the foregoing procedure for manufacturing the lower electrode 131, the lower electrode 131 can be formed to have a film thickness which is smaller at the bottom portion of the depressed portion 150 than at the sidewall thereof. By thus reducing the film thickness of the lower electrode 131 at the bottom portion of the depressed portion 150, it is possible to prevent a reduction in the area of the lower electrode 131, and increase the capacitance of the capacitor 130.

Thus, in an embedded DRAM-logic circuit product and a single DRAM memory, in terms of ensuring a call capacity against process miniaturization, the surface area of the lower electrode has been minimized, and also a uniformly low resistance has been successfully achieved.

In addition, since the first metal film 132 is selectively formed at the sidewall in the depressed portion 150, the surface of the contact 124 exposed at the bottom portion of the depressed portion 150 can be subjected to a wet process in a state where the sidewall of the depressed portion 150 is protected with the first metal film 132. As a result, even when the insulating films in which the depressed portion 150 is formed include a low-dielectric-constant film, it is also possible to prevent moisture used in the wet process from being absorbed into the low-dielectric-constant film.

While the embodiments of the present invention have been described with reference to the drawings, these are exemplary of the present invention, and various configurations other than those described above can also be adopted.

What is claimed is:

1. A method of manufacturing a semiconductor device, comprising the steps of:
forming an insulating film over a substrate;
forming a depressed portion in the insulating film; and
forming, in the depressed portion, a capacitor having a cylindrical shape, and including a lower electrode, a capacitive film formed over the lower electrode, and an upper electrode formed over the capacitive film,
wherein the step of forming the capacitor includes the steps of:
forming a first metal film over an entire upper surface of the substrate to form the first metal film in the depressed portion;
performing anisotropic dry etching to selectively remove the first metal film at a bottom portion of the depressed portion, and leave the first metal film only at a sidewall of the depressed portion; and
forming a second metal film over the entire upper surface of the substrate to form the second metal film over the bottom portion in the depressed portion and over the first metal film at the sidewall therein, and thereby form the lower electrode including the first metal film and the second metal film.

2. A method of manufacturing a semiconductor device according to claim 1,
wherein, in the step of forming the capacitor, the lower electrode is formed to have a film thickness which is smaller at the bottom portion of the depressed portion than at the sidewall thereof.

3. A method of manufacturing a semiconductor device according to claim 1,
wherein, in the step of forming the depressed portion, a contact electrically coupled to an impurity diffusion region of the substrate is exposed at the bottom portion of the depressed portion,
wherein, in the step of leaving the first metal film only at the sidewall of the depressed portion of the step of forming the capacitor, the contact is exposed at the bottom portion of the depressed portion, and
wherein, in the step of forming the lower electrode, the second metal film is formed to come in contact with the contact.

4. A method of manufacturing a semiconductor device according to claim 1,
wherein the step of forming the capacitor further includes, after the step of leaving the first metal film only at the sidewall of the depressed portion and prior to the step of forming the lower electrode, the step of:
performing a wet process to interior of the depressed portion.

5. A semiconductor device including a capacitor formed to have a cylindrical shape, comprising:
a substrate;
an insulating film formed over the substrate;
a lower electrode including a first metal film which is not formed at a bottom portion in a depressed portion provided in the insulating film, but is formed at a sidewall therein, and a second metal film which is formed over the bottom portion in the depressed portion and over the first metal film at the sidewall therein;
a capacitive film formed over the lower electrode; and
an upper electrode formed over the capacitive film.

6. A semiconductor device according to claim 5,
wherein the lower electrode is formed to have a film thickness which is smaller at the bottom portion of the depressed portion than at the sidewall thereof.

7. A semiconductor device according to claim 5,
wherein the first metal film of the lower electrode is formed of TiN, TaN, W, or WN.

8. A semiconductor device according to claim 5,
wherein the second metal film of the lower electrode is formed of TiN, TaN, W, or WN.

9. A semiconductor device according to claim 5, further comprising:
a contact provided under the bottom portion of the depressed portion to be in contact with the second metal film of the lower electrode, and electrically coupled to an impurity diffusion region of the substrate.
